(19) United States
(12) Patent Application Publication
(10) Pub. No.: US 2026/0293284 A1
(43) Pub. Date: Sep. 24, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Masakazu KOBAYASHI, Himeji Hyogo (JP); Yoichi HORI, Himeji Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/269,121

(22) Filed: Jul. 15, 2025

(30) Foreign Application Priority Data
Mar. 24, 2025 (JP) 2025-048575

(51) Int. Cl. H10D 84/00; H10D 62/832

(52) U.S. Cl. CPC H10D 84/146; H10D 62/8325

(57) ABSTRACT

A semiconductor device includes a first semiconductor layer, a second semiconductor layer contacting a first region of the first semiconductor layer, a third semiconductor layer contacting a second region of the first semiconductor layer, a fourth semiconductor layer located on a portion of the second semiconductor layer, and a fifth semiconductor layer located on a portion of the third semiconductor layer. The second semiconductor layer includes carbon. The third semiconductor layer includes argon. An argon concentration of the third semiconductor layer is greater than an argon concentration of the second semiconductor layer. A carbon concentration of the third semiconductor layer is less than a carbon concentration of the second semiconductor layer. A distance between the first region and the third region is less than a distance between the second region and the third region.

### CROSS-REFERENCE TO RELATED APPLICATIONS

This application is based upon and claims the benefit of priority from Japanese Patent Application No. 2025-048575, filed on Mar. 24, 2025; the entire contents of which are incorporated herein by reference.

### FIELD

Embodiments described herein relate generally to a semiconductor device.

### BACKGROUND

MOSFETs (Metal-Oxide-Semiconductor Field-Effect Transistors) that include silicon carbide (SiC) are being developed as semiconductor devices for power control. By using SiC as the semiconductor material, higher switching speeds and lower power losses can be expected.

In a SiC-MOSFET, when a reverse voltage is applied and a current flows through the p-n junction inside the MOSFET, problems occur in that basal plane dislocations decompose, stacking faults grow, and the on-resistance increases. Therefore, a SBD (Schottky Barrier Diode) is arranged in parallel with the MOSFET inside the semiconductor device so that a reverse current flows through the SBD. It is desirable to improve the surge current withstand of such an SBD-embedded MOSFET.

### BRIEF DESCRIPTION OF THE DRAWINGS

FIG. 1 is a plan view showing a silicon carbide part of a semiconductor device according to a first embodiment;

FIG. 2 is a cross-sectional view along line A-A′ shown in FIG. 1;

FIG. 3 is a graph showing effects of carbon and argon on the carrier lifetime, in which the horizontal axis is the concentrations of carbon and argon, and the vertical axis is the carrier lifetime;

FIGS. 4A and 4B are cross-sectional views showing paths of surge current flowing through the semiconductor device according to the first embodiment;

FIG. 5 is a graph showing an I-V characteristic when the surge current flows, in which the horizontal axis is the voltage, and the vertical axis is the current;

FIG. 6 is a cross-sectional view showing a semiconductor device according to a second embodiment;

FIG. 7 is a graph showing effects of carbon and argon on the carrier lifetime, in which the horizontal axis is the concentrations of carbon and argon, and the vertical axis is the carrier lifetime;

FIG. 8 is a cross-sectional view showing a semiconductor device according to a third embodiment;

FIG. 9 is a graph showing effects of carbon and argon on the carrier lifetime, in which the horizontal axis is the concentrations of carbon and argon, and the vertical axis is the carrier lifetime;

FIG. 10 is a cross-sectional view showing a semiconductor device according to a fourth embodiment;

FIG. 11 is a graph showing effects of carbon and argon on the carrier lifetime, in which the horizontal axis is the concentrations of carbon and argon, and the vertical axis is the carrier lifetime;

FIG. 12 is a cross-sectional view showing a semiconductor device according to a fifth embodiment;

FIG. 13 is a graph showing effects of carbon and argon on the carrier lifetime, in which the horizontal axis is the concentrations of carbon and argon, and the vertical axis is the carrier lifetime;

FIG. 14 is a plan view showing a silicon carbide part of a semiconductor device according to a sixth embodiment; and

FIG. 15 is a graph showing a carbon concentration profile and an argon concentration profile in the base layer of the semiconductor device according to the embodiment, in which the horizontal axis is the Y-direction position, and the vertical axis is the concentration.

### DETAILED DESCRIPTION

In general, according to one embodiment, a semiconductor device includes a first electrode, a first semiconductor layer connected to the first electrode, a second semiconductor layer contacting a first region of the first semiconductor layer, a third semiconductor layer contacting a second region of the first semiconductor layer, a fourth semiconductor layer located on a portion of the second semiconductor layer, a fifth semiconductor layer located on a portion of the third semiconductor layer, a second electrode contacting a third region of the first semiconductor layer, an insulating layer located on a part of the first semiconductor layer between the second semiconductor layer and the third semiconductor layer, and a third electrode located on the insulating layer. The first semiconductor layer is of a first conductivity type. The second semiconductor layer is of a second conductivity type and includes carbon. The third semiconductor layer is of the second conductivity type and includes argon. An argon concentration of the third semiconductor layer is greater than an argon concentration of the second semiconductor layer. A carbon concentration of the third semiconductor layer is less than a carbon concentration of the second semiconductor layer. The fourth semiconductor layer is of the first conductivity type. The fifth semiconductor layer is of the first conductivity type. A distance between the first region and the third region is less than a distance between the second region and the third region. The second electrode is connected to the second, third, fourth, and fifth semiconductor layers. The third electrode is insulated from the second electrode.

In general, according to one embodiment, a semiconductor device includes a first electrode, a first semiconductor layer connected to the first electrode, a second semiconductor layer contacting a first region of the first semiconductor layer, a third semiconductor layer contacting a second region of the first semiconductor layer, a fourth semiconductor layer located on a portion of the second semiconductor layer, a fifth semiconductor layer located on a portion of the third semiconductor layer, a second electrode contacting a third region of the first semiconductor layer, an insulating layer located on a part of the first semiconductor layer between the second semiconductor layer and the third semiconductor layer, and a third electrode located on the insulating layer. The first semiconductor layer is of a first conductivity type. The second semiconductor layer is of a second conductivity type. The third semiconductor layer is of the second conductivity type and includes argon. An argon concentration of the third semiconductor layer is greater than an argon concentration of the second semiconductor layer. The fourth semiconductor layer is of the first conductivity type. The fifth semiconductor layer is of the first conductivity type. A distance between the first region and the third region is less than a distance between the second region and the third region. The second electrode is connected to the second, third, fourth, and fifth semiconductor layers. The third electrode is insulated from the second electrode.

In general, according to one embodiment, a semiconductor device includes a first electrode, a first semiconductor layer connected to the first electrode, a second semiconductor layer contacting a first region of the first semiconductor layer, a third semiconductor layer contacting a second region of the first semiconductor layer, a fourth semiconductor layer located on a portion of the second semiconductor layer, a fifth semiconductor layer located on a portion of the third semiconductor layer, a second electrode contacting a third region of the first semiconductor layer, an insulating layer located on a part of the first semiconductor layer between the second semiconductor layer and the third semiconductor layer, and a third electrode located on the insulating layer. The first semiconductor layer is of a first conductivity type. The second semiconductor layer is of a second conductivity type and includes carbon. The third semiconductor layer is of the second conductivity type. A carbon concentration of the third semiconductor layer is less than a carbon concentration of the second semiconductor layer. The fourth semiconductor layer is of the first conductivity type. The fifth semiconductor layer is of the first conductivity type. A distance between the first region and the third region is less than a distance between the second region and the third region. The second electrode is connected to the second, third, fourth, and fifth semiconductor layers. The third electrode is insulated from the second electrode.

### First Embodiment

A semiconductor device according to an embodiment is, for example, a vertical power control semiconductor device, and is an SBD-embedded MOSFET.

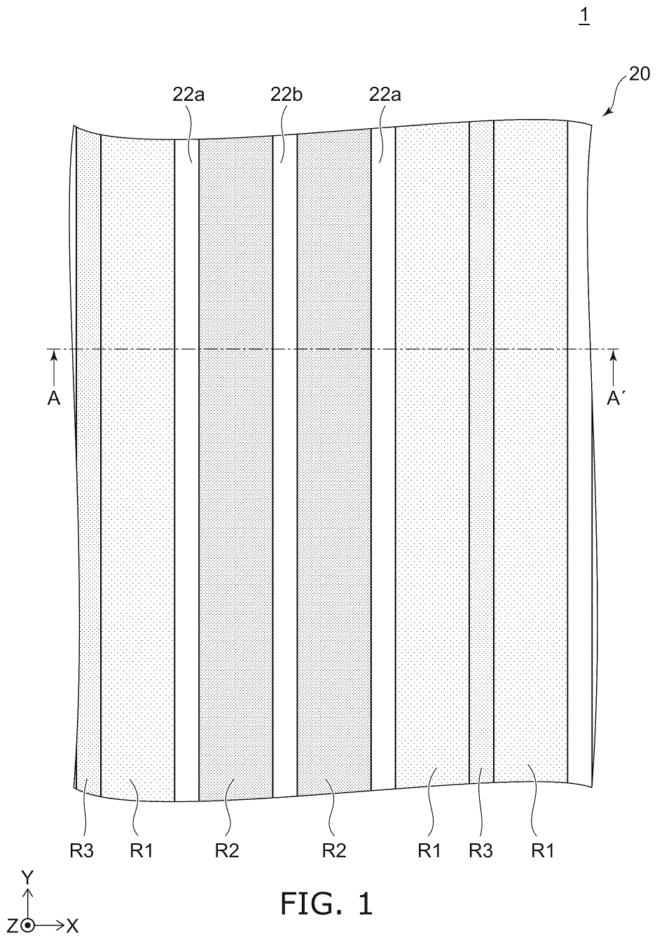

FIG. 1 is a plan view showing a silicon carbide part of the semiconductor device according to the embodiment.

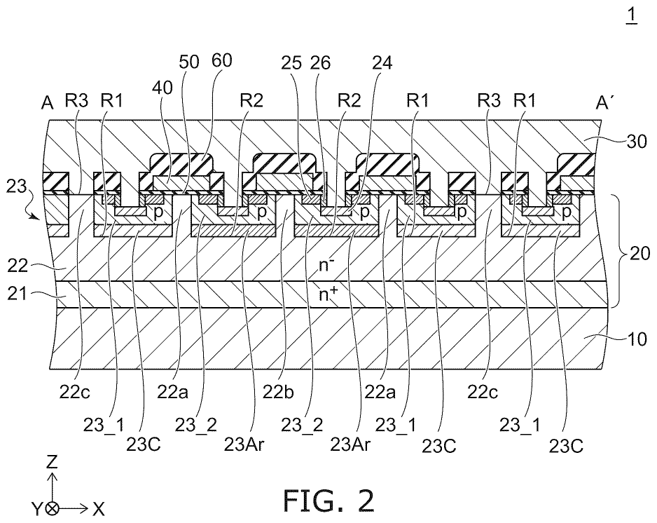

FIG. 2 is a cross-sectional view along line A-A′ shown in FIG. 1.

The drawings are schematic and are appropriately enhanced and simplified. The dimensional ratios and/or positional relationships may not exactly match between the drawings, even for the same component. This is similar for the other drawings described below as well.

As shown in FIGS. 1 and 2, the semiconductor device 1 according to the embodiment includes a drain electrode 10 (a first electrode), a silicon carbide part 20, a source electrode 30 (a second electrode), a gate electrode 40 (a third electrode), a gate insulating layer 50 (an insulating layer), and an inter-layer insulating film 60. The silicon carbide part 20 is located on the drain electrode 10. The source electrode 30, the gate electrode 40, the gate insulating layer 50, and the inter-layer insulating film 60 are located on the silicon carbide part 20.

The silicon carbide part 20 is made of, for example, single-crystal silicon carbide (SiC); and the conductivity type of each portion is set to an n-type or a p-type by introducing a donor or an acceptor. The silicon carbide part 20 includes a drain layer 21, a drift layer 22, a base layer 23, a base contact layer 24, a source layer 25, and a source contact layer 26.

The conductivity type of the drain layer 21 is the n⁺-type. The drain layer 21 is located on the drain electrode 10, contacts the drain electrode 10, and is connected to the drain electrode 10. In the specification, “connected” means an electrical connection.

The conductivity type of the drift layer 22 is the n⁻-type. The drift layer 22 is located on the drain layer 21 and contacts the drain layer 21. The “first semiconductor layer” is formed of the drain layer 21 and the drift layer 22.

In the specification, the “n⁺-type” indicates a higher impurity concentration than the “n-type”; and the “n⁻-type” indicates a lower impurity concentration than the “n-type”. There are also cases where the “n⁻-type”, the “n-type”, and the “n⁺-type” are generally referred to as the “n-type”. This is similar for the p-type as well. The “impurity concentration” refers to the concentration of the impurities contributing to the conductivity of the semiconductor material, and refer to the net concentration excluding the cancelled portion when both an impurity that forms donors and an impurity that forms acceptors are included in one region.

The conductivity type of the base layer 23 is the p-type. The silicon carbide part 20 includes multiple base layers 23. Some of the base layers 23 contact first regions R1 of the drift layer 22; and other base layers 23 contact second regions R2 of the drift layer 22. As necessary hereinbelow, the base layer 23 that contacts the first region R1 of the drift layer 22 is referred to as the “base layer 23_1”; and the base layer 23 that contacts the second region R2 of the drift layer 22 is referred to as the “base layer 23_2”. The “base layer 23_1” and the “base layer 23_2” also are generally referred to as the “base layer 23”.

In the specification, an XYZ orthogonal coordinate system is employed for convenience of description. The direction from the drain electrode 10 toward the source electrode 30 is referred to as a “Z-direction”; the direction in which the multiple base layers 23 are arranged is referred to as an “X-direction”; and a direction orthogonal to the Z-direction and X-direction is referred to as a “Y-direction”. Although the Z-direction also is referred to as “up” or “above” and the opposite direction also is referred to as “down” or “below”, these expressions are for convenience and are independent of the direction of gravity.

Each base layer 23 extends in the Y-direction. In other words, the first region R1 and the second region R2 extend in the Y-direction. A carbon implantation layer 23C is located in the lower part of the base layer 23_1. Carbon (C) is ion-implanted into the carbon implantation layer 23C. An argon implantation layer 23Ar is located in the lower part of the base layer 23_2. Argon (Ar) is ion-implanted into the argon implantation layer 23Ar. Therefore, the carbon concentration of the entire base layer 23_1 is greater than the carbon concentration of the entire base layer 23_2. Also, the argon concentration of the entire base layer 23_2 is greater than the argon concentration of the entire base layer 23_1. The argon concentration of the base layer 231 may be substantially zero; and the carbon concentration of the entire base layer 23_2 may be substantially zero.

The conductivity type of the base contact layer 24 is the p⁺-type. The base contact layer 24 is located at the X-direction central portion of the upper part of each base layer 23 and contacts the base layer 23. The base contact layer 24 is separated from the drift layer 22 by the base layer 23. The “second semiconductor layer” is formed of the base layer 23_1 and the base contact layer 24 on the base layer 23_1; and the “third semiconductor layer” is formed of the base layer 23_2 and the base contact layer 24 on the base layer 23_2.

The conductivity type of the source layer 25 is the n-type. The source layer 25 is located in a portion of the upper part of the base layer 23. The source layer 25 is separated from the drift layer 22 by the base layer 23. The conductivity type of the source contact layer 26 is the n⁺-type. The source contact layer 26 contacts the source layer 25. The “fourth semiconductor layer” is formed of the source layer 25 and the source contact layer 26 located on the base layer 23_1; and the “fifth semiconductor layer” is formed of the source layer 25 and the source contact layer 26 located on the base layer 23_2.

The gate insulating layer 50 is located on the silicon carbide part 20 in the region directly above a part 22a of the drift layer 22 between the base layer 23_1 and the base layer 23_2, in the region directly above a part 22b of the drift layer 22 between two mutually-adjacent base layers 23_2, in the region directly above a part of the base layer 23 between the drift layer 22 and the source layer 25, in the region directly above the source layer 25, and in the region directly above the source contact layer 26.

The gate electrode 40 is located on a portion of the gate insulating layer 50. The gate electrode 40 is located in the region directly above the part 22a of the drift layer 22, in the region directly above the part 22b of the drift layer 22, in the region directly above the part of the base layer 23 between the drift layer 22 and the source layer 25, and in the region directly above the part of the source layer 25 separated from the source contact layer 26.

The inter-layer insulating film 60 is located on the silicon carbide part 20 and covers the gate insulating layer 50 and the gate electrode 40. The source electrode 30 is located on the silicon carbide part 20 and covers the gate insulating layer 50, the gate electrode 40, and the inter-layer insulating film 60. The gate electrode 40 is insulated from the source electrode 30 by the inter-layer insulating film 60.

The source electrode 30 contacts a part 22c of the upper surface of the drift layer 22 between two mutually-adjacent base layers 23_1. The contact surface between the part 22c and the source electrode 30 is referred to as a “third region R3”. The third region R3 extends in the Y-direction. In the third region R3, the source electrode 30 and the drift layer 22 have a Schottky barrier junction and form a Schottky barrier diode.

The source electrode 30 contacts the base contact layer 24 and the source contact layer 26 and has ohmic connections with the base contact layer 24 and the source contact layer 26. As a result, a MOSFET is formed in the first and second regions R1 and R2; and a p-n diode is formed of the base layer 23 and the drift layer 22.

Relatively, the first region R1 is proximate to the third region R3; and the second region R2 is distant to the third region R3. In other words, a first distance between the first region R1 and the third region R3 is less than a second distance between the second region R2 and the third region R3.

According to the embodiment, the first region R1 is located between the second region R2 and the third region R3 when viewed along the Z-direction. For example, along the X-direction, two first regions R1 are located between two third regions R3; and two second regions R2 are located between these two first regions R1. However, the arrangement of the regions is not limited thereto; and it is sufficient for the first distance between the first region R1 and the third region R3 to be less than the second distance between the second region R2 and the third region R3.

Operations and effects of the embodiment will now be described.

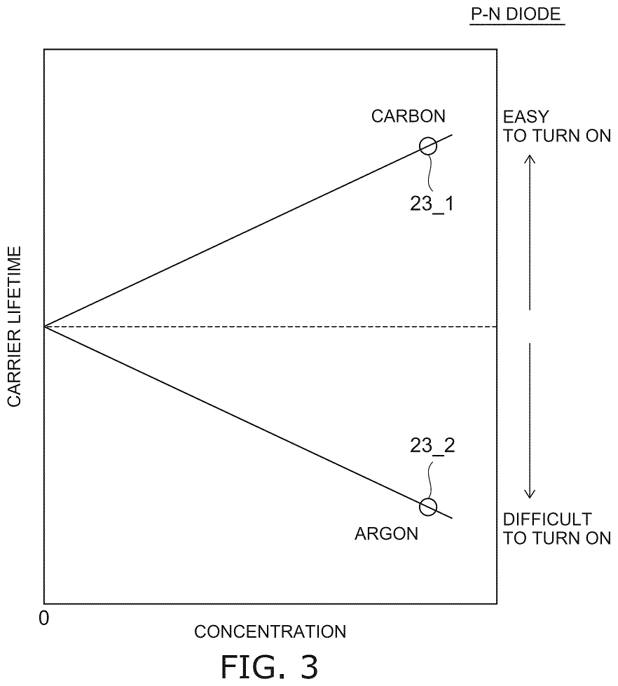

FIG. 3 is a graph showing the effects of carbon and argon on the carrier lifetime, in which the horizontal axis is the concentrations of carbon and argon, and the vertical axis is the carrier lifetime.

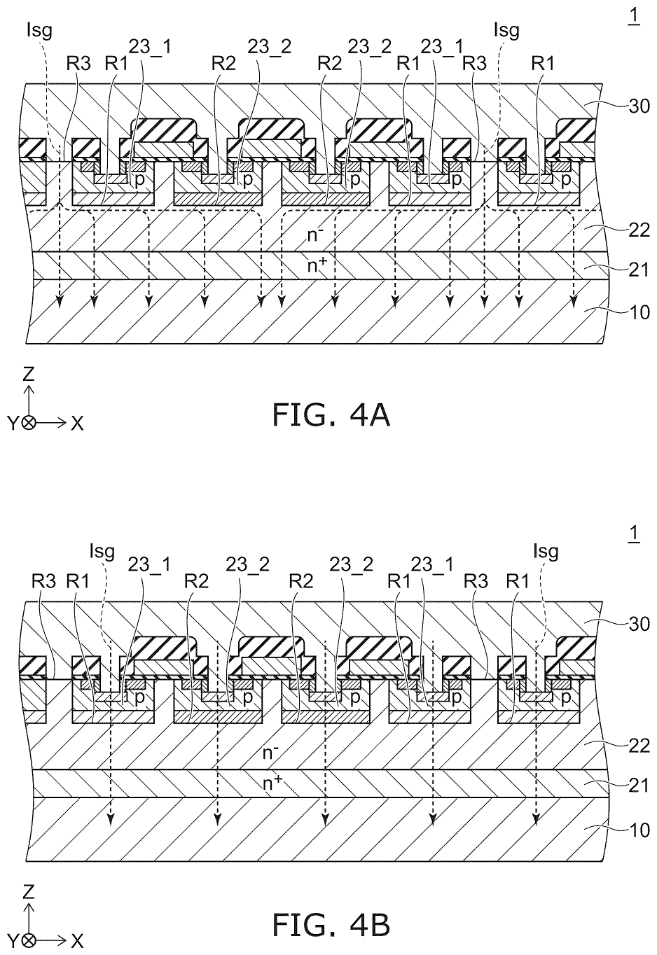

FIGS. 4A and 4B are cross-sectional views showing paths of surge current flowing through the semiconductor device according to the embodiment.

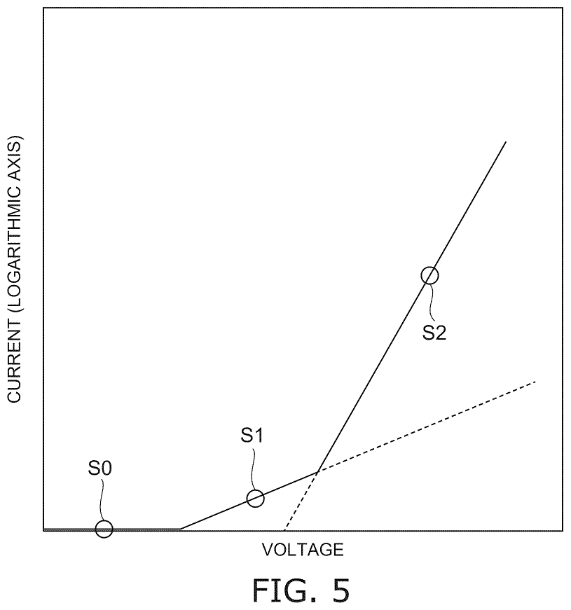

FIG. 5 is a graph showing an I-V characteristic when the surge current flows, in which the horizontal axis is the voltage, and the vertical axis is the current.

As shown in FIG. 3, the carrier lifetime decreases as the argon concentration in the silicon carbide increases. It is considered that this is because defects are introduced by the implantation of argon; and pair annihilation of electrons and holes occurs more easily at the defects. On the other hand, the carrier lifetime increases as the carbon concentration in the silicon carbide increases. It is considered that this is because carbon in the silicon carbide escapes to form defects due to heat treatment during the manufacturing processes of the semiconductor device 1, but the implanted carbon fills the defects and causes the defects to disappear.

The p-n diode is easier to turn on as the carrier lifetime increases; and the p-n diode is more difficult to turn on as the carrier lifetime decreases. Therefore, the p-n diode made of the base layer 23_1 and the drift layer 22 in the first region R1 is turned on relatively easily; and the p-n diode made of the base layer 23_2 and the drift layer 22 in the second region R2 is relatively difficult to turn on.

As shown in a state S0 of FIGS. 2 and 5, in the semiconductor device 1, when the drain electrode 10 is negative, the source electrode 30 is positive, and the magnitude of the voltage is less than a prescribed value, a current does not flow in the Schottky barrier diode of the third region R3; currents do not flow in the p-n diodes of the first and second regions R1 and R2; therefore, a current substantially does not flow in the semiconductor device 1.

As shown in a state S1 of FIGS. 4A and 5, when a surge voltage is applied to the semiconductor device 1, and when the voltage applied to the drain electrode 10 and the source electrode 30 becomes the prescribed value or more, a surge current Isg starts to flow. The surge current Isg passes from the source electrode 30 through the Schottky barrier diode in the forward direction via the third region R3, diffuses in the X-direction inside the drift layer 22, and flows to the drain electrode 10 via the drain layer 21.

At this time, the potential decreases away from the third region R3 of the drift layer 22 due to the voltage drop accompanying the flow of the surge current Isg. Therefore, the potential difference between the base layer 23_2 and the drift layer 22 in the second region R2 is greater than the potential difference between the base layer 23_1 and the drift layer 22 in the first region R1. On the other hand, as described above, the p-n diode formed in the second region R2 is more difficult to turn on than the p-n diode formed in the first region R1. As a result, the effect of the p-n potential difference being greater in the second region R2 than the first region R1 and the effect of the p-n diode of the second region R2 being more difficult to turn on than the p-n diode of the first region R1 cancel each other, and all of the p-n diodes are switched to the on-state at substantially the same timing as shown in FIG. 4B.

As a result, as illustrated by a state S2 of FIG. 5, the surge current Isg flows in the p-n diodes of the first and second regions R1 and R2 in addition to the Schottky barrier diode of the third region R3. As a result, the surge current Isg can be quickly discharged, and breakdown of the semiconductor device 1 can be suppressed.

Thus, according to the embodiment, the semiconductor device 1 can be realized in which surge current withstand can be improved.

In contrast, if the carbon implantation layer 23C is not included in the base layer 23_1 and the argon implantation layer 23Ar is not included in the base layer 232, the p-n diodes are equally easy to turn on. In such a case, the voltage drop due to the surge current Isg causes the p-n diode of the second region R2 to be easier to turn on than the p-n diode of the first region R1. As a result, it takes more time to discharge the surge current Isg because only the p-n diode of the second region R2 is in the on-state; and the current concentrates more easily in the p-n diode of the second region R2. As a result, the likelihood of breakdown of the semiconductor device due to the surge current Isg is higher.

### Second Embodiment

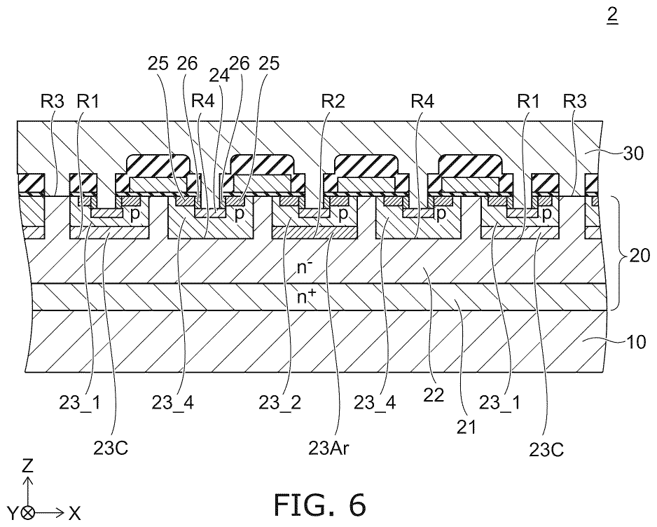

FIG. 6 is a cross-sectional view showing a semiconductor device according to an embodiment.

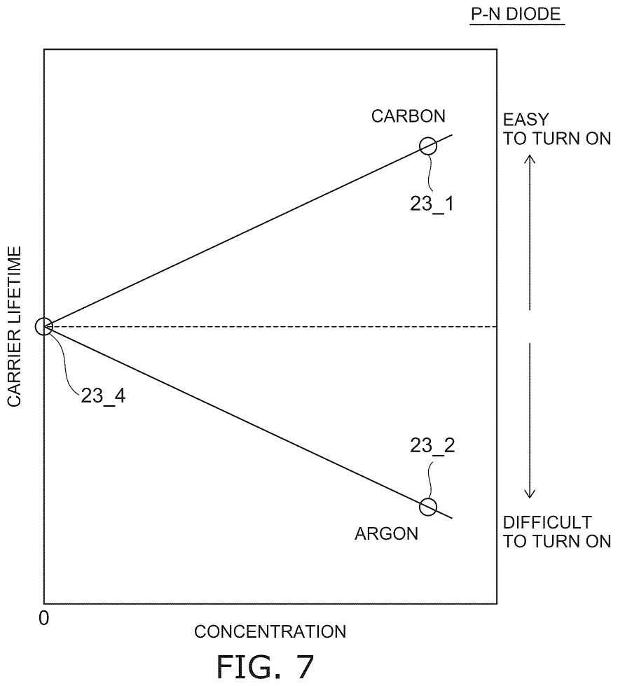

FIG. 7 is a graph showing the effects of carbon and argon on the carrier lifetime, in which the horizontal axis is the concentrations of carbon and argon, and the vertical axis is the carrier lifetime.

As shown in FIG. 6, the semiconductor device 2 according to the embodiment differs from the semiconductor device 1 according to the first embodiment in that a fourth region R4 of the drift layer 22 is located between the first region R1 and the second region R2. A fourth distance between the fourth region R4 and the third region R3 is greater than the first distance between the first region R1 and the third region R3 and less than the second distance between the second region R2 and the third region R3.

The base layer 23 is located on the fourth region R4 and contacts the fourth region R4. The base layer 23 that contacts the fourth region R4 is referred to as the “base layer 23_4”. The base layer 23_4 includes neither the carbon implantation layer 23C nor the argon implantation layer 23Ar. On the other hand, similarly to the first embodiment, the carbon implantation layer 23C is located in the lower part of the base layer 23_1; and the argon implantation layer 23Ar is located in the lower part of the base layer 23_2. Therefore, the carbon concentration of the base layer 23_4 is less than the carbon concentration of the base layer 23_1; and the argon concentration of the base layer 23_4 is less than the argon concentration of the base layer 23_2. The carbon concentration and the argon concentration of the base layer 23_4 may be substantially zero.

The base contact layer 24 also is located on the base layer 23_4. The “sixth semiconductor layer” includes the base layer 23_4 and the base contact layer 24 on the base layer 23_4. The source layer 25 and the source contact layer 26 also are located on a portion of the base layer 23_4. The “seventh semiconductor layer” includes the source layer 25 and the source contact layer 26 located on the base layer 23_4.

As shown in FIG. 7, neither carbon nor argon is introduced to the base layer 234, and so the carrier lifetime of the base layer 23_4 is shorter than the carrier lifetime of the base layer 23_1 and longer than the carrier lifetime of the base layer 23_2. As a result, the p-n diode made of the base layer 23_4 and the drift layer 22 is more difficult to turn on than the p-n diode made of the base layer 23_1 and the drift layer 22 and easier to turn on than the p-n diode made of the base layer 231 and the drift layer 22.

Thus, by controlling the ease of turning the p-n diodes on in three stages according to the distance from the Schottky barrier diode, all of the p-n diodes can be switched to the on-state at the same timing with higher accuracy. As a result, the surge current Isg can be quickly discharged more reliably, and the surge current withstand can be further improved. Otherwise, the configuration, operations, and effects according to the embodiment are similar to those of the first embodiment. The ease of turning the p-n diode on may be controlled in four or more stages according to the distance from the Schottky barrier diode.

### Third Embodiment

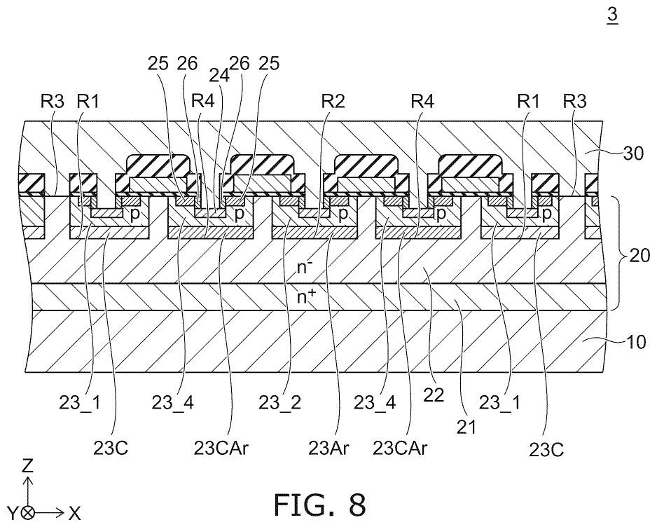

FIG. 8 is a cross-sectional view showing a semiconductor device according to an embodiment.

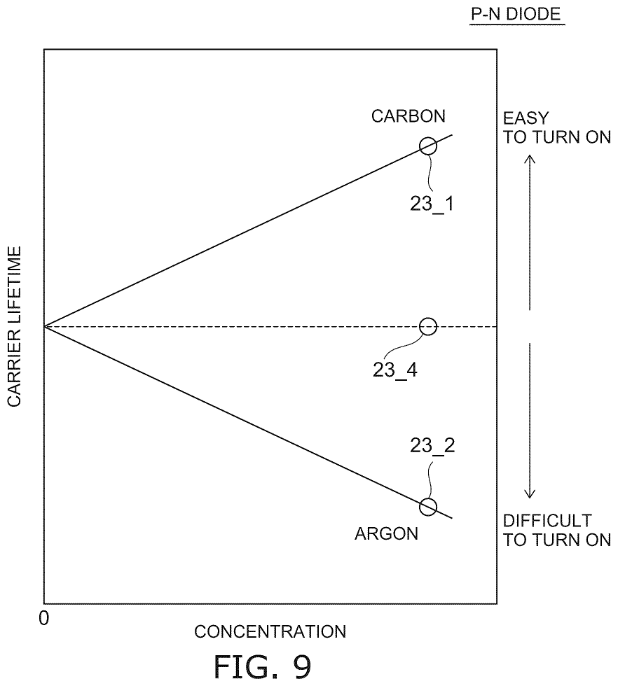

FIG. 9 is a graph showing the effects of carbon and argon on the carrier lifetime, in which the horizontal axis is the concentrations of carbon and argon, and the vertical axis is the carrier lifetime.

As shown in FIG. 8, the semiconductor device 3 according to the embodiment differs from the semiconductor device 2 according to the second embodiment in that the base layer 23_4 includes a carbon/argon implantation layer 23CAr. Carbon and argon are ion-implanted into the carbon/argon implantation layer 23CAr.

As a result, as shown in FIG. 9, the carrier lifetime of the base layer 23_4 is shorter than the carrier lifetime of the base layer 23_1 and longer than the carrier lifetime of the base layer 23_2. As a result, effects similar to those of the second embodiment can be obtained. Otherwise, the configuration, operations, and effects according to the embodiment are similar to those of the second embodiment.

### Fourth Embodiment

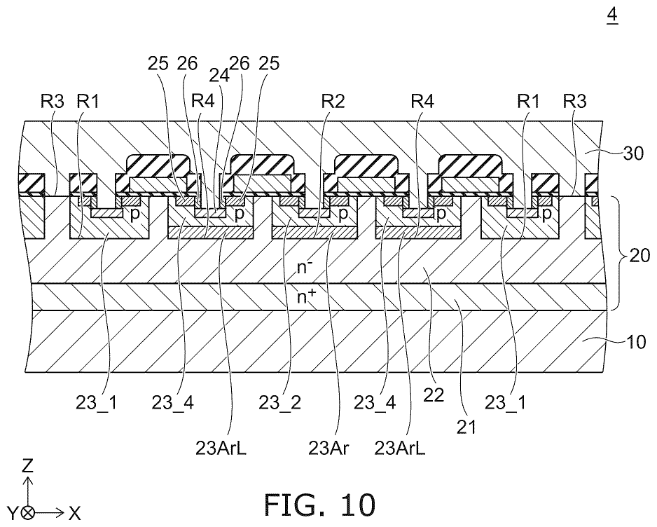

FIG. 10 is a cross-sectional view showing a semiconductor device according to an embodiment.

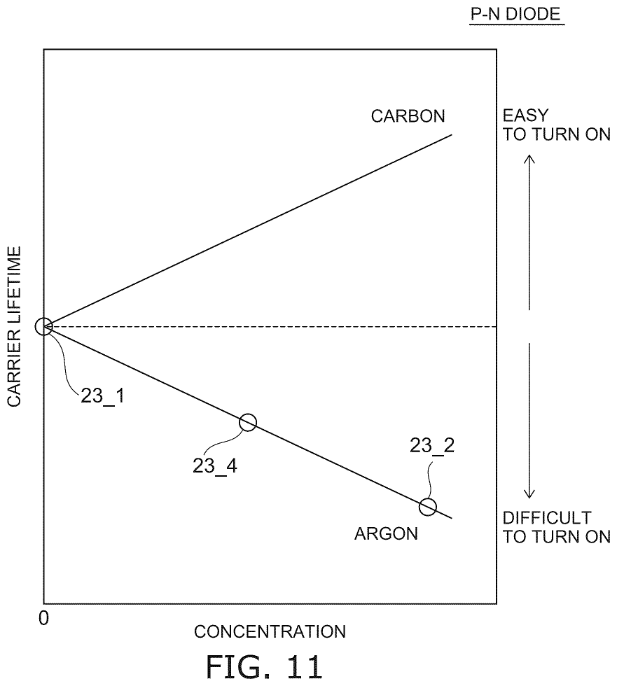

FIG. 11 is a graph showing the effects of carbon and argon on the carrier lifetime, in which the horizontal axis is the concentrations of carbon and argon, and the vertical axis is the carrier lifetime.

As shown in FIG. 10, the semiconductor device 4 according to the embodiment differs from the semiconductor device 2 according to the second embodiment in that the base layer 23_1 does not include the carbon implantation layer 23C, and the base layer 23_4 includes a low-concentration argon implantation layer 23ArL. Although argon is implanted into the low-concentration argon implantation layer 23ArL, the implantation amount is less than that of the argon implantation layer 23Ar. Similarly to the second embodiment, the base layer 23_2 includes the argon implantation layer 23Ar.

In the semiconductor device 4, the argon concentration of the base layer 23_4 formed in the fourth region R4 is greater than the argon concentration of the base layer 23_1 formed in the first region R1 and less than the argon concentration of the base layer 23_2 formed in the second region R2. Therefore, as shown in FIG. 11, the p-n diode between the base layer 23_4 and the drift layer 22 is more difficult to turn on than the p-n diode between the base layer 231 and the drift layer 22 and easier to turn on than the p-n diode between the base layer 23_2 and the drift layer 22.

As a result, all of the p-n diodes can be switched to the on-state at substantially the same timing. According to the embodiment, the characteristics of the p-n diodes can be adjusted without implanting carbon. Otherwise, the configuration, operations, and effects according to the embodiment are similar to those of the second embodiment.

The on-characteristics of the p-n diodes may be controlled in two stages by including only the base layer 23_1 and the base layer 23_2 without including the base layer 23_4.

### Fifth Embodiment

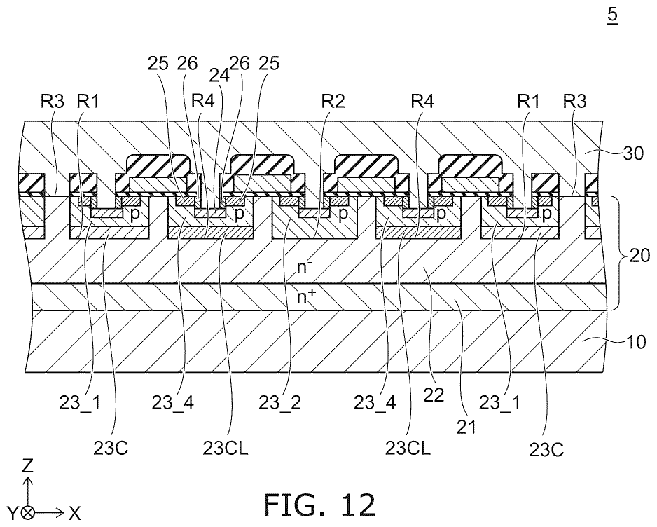

FIG. 12 is a cross-sectional view showing a semiconductor device according to an embodiment.

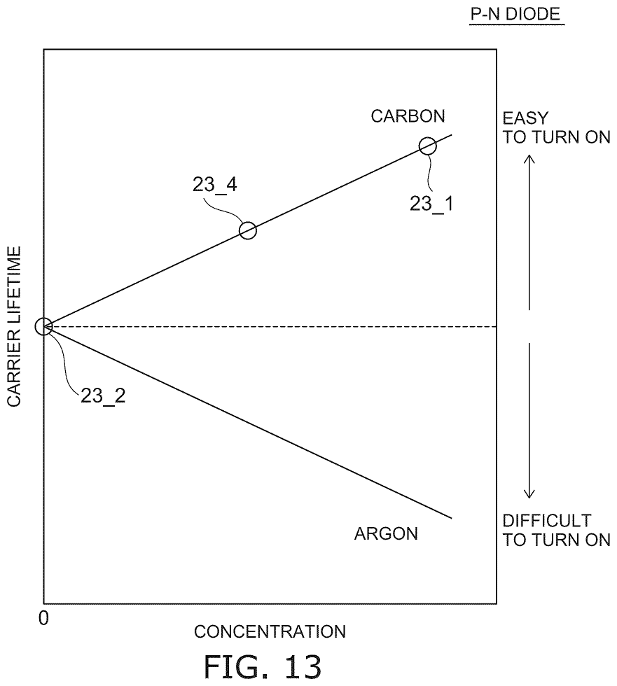

FIG. 13 is a graph showing the effects of carbon and argon on the carrier lifetime, in which the horizontal axis is the concentrations of carbon and argon, and the vertical axis is the carrier lifetime.

As shown in FIG. 12, the semiconductor device 5 according to the embodiment differs from the semiconductor device 2 according to the second embodiment in that the base layer 23_2 does not include the argon implantation layer 23Ar, and the base layer 23_4 includes a low-concentration carbon implantation layer 23CL. Although carbon is implanted into the low-concentration carbon implantation layer 23CL, the implantation amount is less than that of the carbon implantation layer 23C. Similarly to the second embodiment, the base layer 23_1 includes the carbon implantation layer 23C.

In the semiconductor device 5, the carbon concentration of the base layer 23_4 formed in the fourth region R4 is less than the carbon concentration of the base layer 23_1 formed in the first region R1 and greater than the carbon concentration of the base layer 23_2 formed in the second region R2. Therefore, as shown in FIG. 13, the p-n diode between the base layer 23_4 and the drift layer 22 is more difficult to turn on than the p-n diode between the base layer 231 and the drift layer 22 and easier to turn on than the p-n diode between the base layer 23_2 and the drift layer 22.

As a result, all of the p-n diodes can be switched to the on-state at substantially the same timing. According to the embodiment, the characteristics of the p-n diodes can be adjusted without implanting argon. Otherwise, the configuration, operations, and effects according to the embodiment are similar to those of the second embodiment. The on-characteristics of the p-n diodes may be controlled in two stages by including only the base layer 23_1 and the base layer 23_2 without including the base layer 23_4.

### Sixth Embodiment

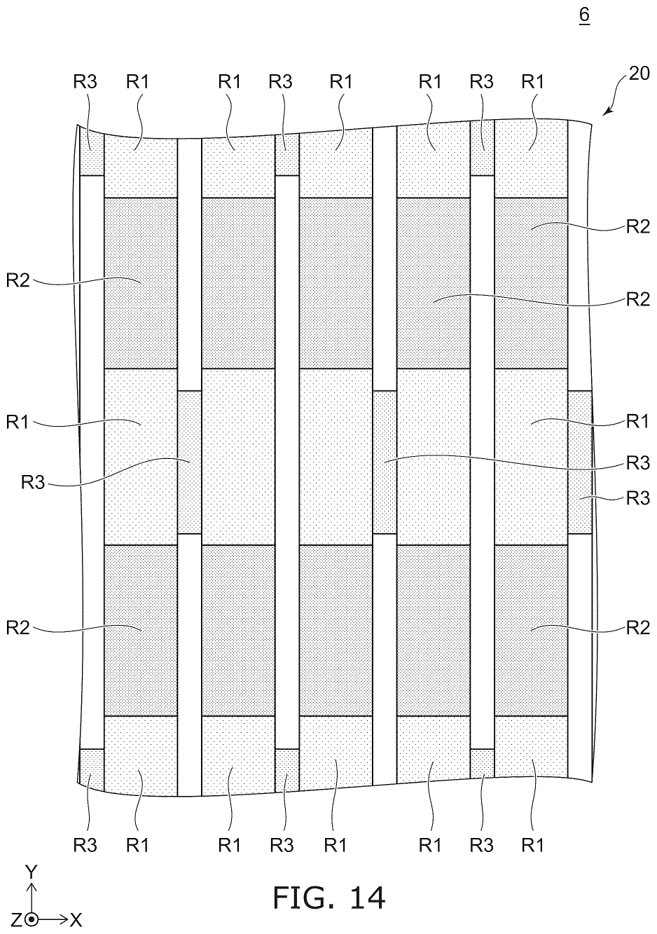

FIG. 14 is a plan view showing a silicon carbide part of a semiconductor device according to an embodiment.

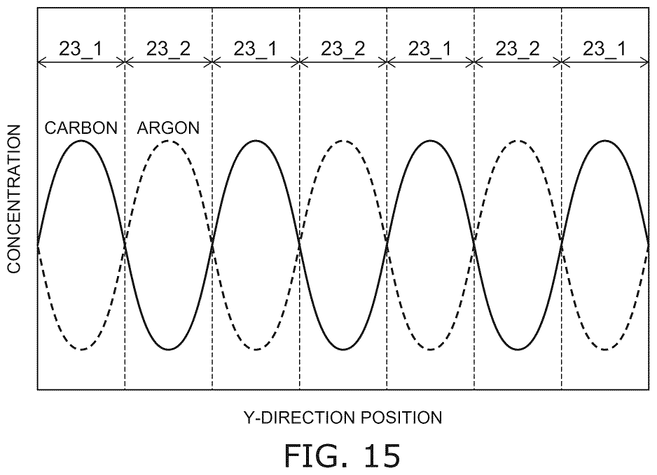

FIG. 15 is a graph showing a carbon concentration profile and an argon concentration profile in the base layer of the semiconductor device according to the embodiment, in which the horizontal axis is the Y-direction position, and the vertical axis is the concentration.

In the semiconductor device 6 according to the embodiment as shown in FIG. 14, the third region R3 is arranged in a staggered configuration along the X-direction and Y-direction. In other words, multiple columns are arranged along the X-direction; and each column includes the multiple third regions R3 discontinuously arranged along the Y-direction. The Y-direction positions of the third regions R3 are different from each other between columns adjacent to each other in the X-direction.

The first regions R1 are located at the two X-direction sides when viewed from the third region R3; and the second region R2 is located between two first regions R1 adjacent to each other in the Y-direction. In such a case as well, the distance between the center of the first region R1 and the center of the third region R3 when viewed along the Z-direction is less than the distance between the center of the second region R2 and the center of the third region R3.

Similarly to the first embodiment, according to the embodiment as well, in the third region R3, the source electrode 30 contacts the drift layer 22; and a Schottky barrier diode is formed. The first region R1 and the second region R2 respectively include the base layer 23_1 and the base layer 23_2. The base layer 231 and the base layer 23_2 are alternately arranged along the Y-direction; and the base layer 23_1 and the base layer 23_2 that are adjacent to each other contact each other. The carbon implantation layer 23C is located in the lower part of the base layer 23_1; and the argon implantation layer 23Ar is located in the lower part of the base layer 23_2.

The boundary between the base layer 23_1 and the base layer 23_2 adjacent to each other in the Y-direction may not always be clear. For example, as illustrated by the solid line in FIG. 15, the carbon concentration profile along the Y-direction may continuously change to have a maximum value at the Y-direction central portion vicinity of the base layer 23_1 and a minimum value at the Y-direction central portion vicinity of the base layer 23_2. Also, as illustrated by the broken line in FIG. 15, the argon concentration profile along the Y-direction may continuously change to have a maximum value at the Y-direction central portion vicinity of the base layer 23_2 and a minimum value at the Y-direction central portion vicinity of the base layer 23_1.

As a result, as shown in FIG. 3, compared to the p-n diode made of the base layer 231 and the drift layer 22, the p-n diode made of the base layer 232 and the drift layer 22 has a shorter carrier lifetime, and is more difficult to turn on. On the other hand, the part of the drift layer 22 positioned in the region directly under the base layer 23_2 is more distant to the third region R3 than the part of the drift layer 22 positioned in the region directly under the base layer 23_1, and so the potential when the surge current Isg flows is low.

Because these effects cancel, similarly to the first embodiment, all of the p-n diodes can be switched to the on-state at substantially the same timing when the surge current Isg flows. As a result, the withstand to the surge current Isg is improved. Otherwise, the configuration, operations, and effects according to the embodiment are similar to those of the first embodiment.

An example is illustrated in the embodiment in which both carbon and argon are implanted into the base layer 23, and so the concentration profiles of carbon and argon have substantially complimentary waveforms as shown in FIG. 15. In contrast, when only argon is implanted as in the fourth embodiment above, only the concentration profile of argon is realized as illustrated by the broken line in FIG. 15. When only carbon is implanted as in the fifth embodiment above, only the concentration profile of carbon is realized as illustrated by the solid line in FIG. 15.

Although examples are illustrated in the embodiments above in which argon is ion-implanted to introduce defects and shorten the carrier lifetime, the ion species implanted to introduce defects is not limited to argon, and may be, for example, protons or electrons.

According to the embodiments above, a semiconductor device can be realized in which the surge current withstand can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

Embodiments include the following aspects.

### Note 1

A semiconductor device, comprising:
a first electrode;
a first semiconductor layer connected to the first electrode, the first semiconductor layer being of a first conductivity type;
a second semiconductor layer contacting a first region of the first semiconductor layer, the second semiconductor layer being of a second conductivity type and including carbon;
a third semiconductor layer contacting a second region of the first semiconductor layer, the third semiconductor layer being of the second conductivity type and including argon, an argon concentration of the third semiconductor layer being greater than an argon concentration of the second semiconductor layer, a carbon concentration of the third semiconductor layer being less than a carbon concentration of the second semiconductor layer;
a fourth semiconductor layer located on a portion of the second semiconductor layer, the fourth semiconductor layer being of the first conductivity type;
a fifth semiconductor layer located on a portion of the third semiconductor layer, the fifth semiconductor layer being of the first conductivity type;
a second electrode contacting a third region of the first semiconductor layer, a distance between the first region and the third region being less than a distance between the second region and the third region, the second electrode being connected to the second, third, fourth, and fifth semiconductor layers;
an insulating layer located on a part of the first semiconductor layer between the second semiconductor layer and the third semiconductor layer; and
a third electrode located on the insulating layer, the third electrode being insulated from the second electrode.

### Note 2

The device according to note 1, further comprising:
a sixth semiconductor layer contacting a fourth region of the first semiconductor layer, the sixth semiconductor layer being of the second conductivity type, an argon concentration of the sixth semiconductor layer being less than the argon concentration of the third semiconductor layer, a carbon concentration of the sixth semiconductor layer being less than the carbon concentration of the second semiconductor layer; and
a seventh semiconductor layer located on a portion of the sixth semiconductor layer, the seventh semiconductor layer being of the first conductivity type,
a distance between the fourth region and the third region being greater than the distance between the first region and the third region and less than the distance between the second region and the third region.

### Note 3

A semiconductor device, comprising:
a first electrode;
a first semiconductor layer connected to the first electrode, the first semiconductor layer being of a first conductivity type;
a second semiconductor layer contacting a first region of the first semiconductor layer, the second semiconductor layer being of a second conductivity type;
a third semiconductor layer contacting a second region of the first semiconductor layer, the third semiconductor layer being of the second conductivity type and including argon, an argon concentration of the third semiconductor layer being greater than an argon concentration of the second semiconductor layer;
a fourth semiconductor layer located on a portion of the second semiconductor layer, the fourth semiconductor layer being of the first conductivity type;
a fifth semiconductor layer located on a portion of the third semiconductor layer, the fifth semiconductor layer being of the first conductivity type;
a second electrode contacting a third region of the first semiconductor layer, a distance between the first region and the third region being less than a distance between the second region and the third region, the second electrode being connected to the second, third, fourth, and fifth semiconductor layers;
an insulating layer located on a part of the first semiconductor layer between the second semiconductor layer and the third semiconductor layer; and
a third electrode located on the insulating layer, the third electrode being insulated from the second electrode.

### Note 4

The device according to note 3, further comprising:
a sixth semiconductor layer contacting a fourth region of the first semiconductor layer, the sixth semiconductor layer being of the second conductivity type and including argon, an argon concentration of the sixth semiconductor layer being greater than the argon concentration of the second semiconductor layer and less than the argon concentration of the third semiconductor layer; and
a seventh semiconductor layer located on a portion of the sixth semiconductor layer, the seventh semiconductor layer being of the first conductivity type,
a distance between the fourth region and the third region being greater than the distance between the first region and the third region and less than the distance between the second region and the third region.

### Note 5

A semiconductor device, comprising:
a first electrode;
a first semiconductor layer connected to the first electrode, the first semiconductor layer being of a first conductivity type;
a second semiconductor layer contacting a first region of the first semiconductor layer, the second semiconductor layer being of a second conductivity type and including carbon;
a third semiconductor layer contacting a second region of the first semiconductor layer, the third semiconductor layer being of the second conductivity type, a carbon concentration of the third semiconductor layer being less than a carbon concentration of the second semiconductor layer;
a fourth semiconductor layer located on a portion of the second semiconductor layer, the fourth semiconductor layer being of the first conductivity type;
a fifth semiconductor layer located on a portion of the third semiconductor layer, the fifth semiconductor layer being of the first conductivity type;
a second electrode contacting a third region of the first semiconductor layer, a distance between the first region and the third region being less than a distance between the second region and the third region, the second electrode being connected to the second, third, fourth, and fifth semiconductor layers;
an insulating layer located on a part of the first semiconductor layer between the second semiconductor layer and the third semiconductor layer; and
a third electrode located on the insulating layer, the third electrode being insulated from the second electrode.

### Note 6

The device according to note 5, further comprising:
a sixth semiconductor layer contacting a fourth region of the first semiconductor layer, the sixth semiconductor layer being of the second conductivity type and including carbon, a carbon concentration of the sixth semiconductor layer being less than the carbon concentration of the second semiconductor layer and greater than the carbon concentration of the third semiconductor layer; and
a seventh semiconductor layer located on a portion of the sixth semiconductor layer, the seventh semiconductor layer being of the first conductivity type,
a distance between the fourth region and the third region being greater than the distance between the first region and the third region and less than the distance between the second region and the third region.

### Note 7

The device according to any one of notes 1 to 6, wherein
the first region is located between the second region and the third region when viewed along a first direction, and
the first direction is from the first electrode toward the second electrode.

### Note 8

The device according to any one of notes 1 to 7, wherein
the first region, the second region, and the third region extend in a second direction crossing a first direction, and
the first direction is from the first electrode toward the second electrode.

### Note 9

The device according to any one of notes 1 to 6, wherein
the third region is arranged in a staggered configuration along a second direction and a third direction,
the second direction crosses a first direction,
the first direction is from the first electrode toward the second electrode,
the third direction crosses the first and second directions,
the first region is located in the second direction when viewed from the third region, and
the second region is located between two of the first regions in the third direction.

What is claimed is:

1. A semiconductor device, comprising:
a first electrode;
a first semiconductor layer connected to the first electrode, the first semiconductor layer being of a first conductivity type;
a second semiconductor layer contacting a first region of the first semiconductor layer, the second semiconductor layer being of a second conductivity type and including carbon;
a third semiconductor layer contacting a second region of the first semiconductor layer, the third semiconductor layer being of the second conductivity type and including argon, an argon concentration of the third semiconductor layer being greater than an argon concentration of the second semiconductor layer, a carbon concentration of the third semiconductor layer being less than a carbon concentration of the second semiconductor layer;
a fourth semiconductor layer located on a portion of the second semiconductor layer, the fourth semiconductor layer being of the first conductivity type;
a fifth semiconductor layer located on a portion of the third semiconductor layer, the fifth semiconductor layer being of the first conductivity type;
a second electrode contacting a third region of the first semiconductor layer, a distance between the first region and the third region being less than a distance between the second region and the third region, the second electrode being connected to the second, third, fourth, and fifth semiconductor layers;
an insulating layer located on a part of the first semiconductor layer between the second semiconductor layer and the third semiconductor layer; and
a third electrode located on the insulating layer, the third electrode being insulated from the second electrode.

2. The device according to claim 1, further comprising:
a sixth semiconductor layer contacting a fourth region of the first semiconductor layer, the sixth semiconductor layer being of the second conductivity type, an argon concentration of the sixth semiconductor layer being less than the argon concentration of the third semiconductor layer, a carbon concentration of the sixth semiconductor layer being less than the carbon concentration of the second semiconductor layer; and
a seventh semiconductor layer located on a portion of the sixth semiconductor layer, the seventh semiconductor layer being of the first conductivity type,
a distance between the fourth region and the third region being greater than the distance between the first region and the third region and less than the distance between the second region and the third region.

3. The device according to claim 1, wherein
the first region is located between the second region and the third region when viewed along a first direction, and
the first direction is from the first electrode toward the second electrode.

4. The device according to claim 1, wherein
the first region, the second region, and the third region extend in a second direction crossing a first direction, and
the first direction is from the first electrode toward the second electrode.

5. The device according to claim 1, wherein
the third region is arranged in a staggered configuration along a second direction and a third direction,
the second direction crosses a first direction,
the first direction is from the first electrode toward the second electrode,
the third direction crosses the first and second directions,
the first region is located in the second direction when viewed from the third region, and
the second region is located between two of the first regions in the third direction.

6. A semiconductor device, comprising:
a first electrode;
a first semiconductor layer connected to the first electrode, the first semiconductor layer being of a first conductivity type;
a second semiconductor layer contacting a first region of the first semiconductor layer, the second semiconductor layer being of a second conductivity type;
a third semiconductor layer contacting a second region of the first semiconductor layer, the third semiconductor layer being of the second conductivity type and including argon, an argon concentration of the third semiconductor layer being greater than an argon concentration of the second semiconductor layer;
a fourth semiconductor layer located on a portion of the second semiconductor layer, the fourth semiconductor layer being of the first conductivity type;
a fifth semiconductor layer located on a portion of the third semiconductor layer, the fifth semiconductor layer being of the first conductivity type;
a second electrode contacting a third region of the first semiconductor layer, a distance between the first region and the third region being less than a distance between the second region and the third region, the second electrode being connected to the second, third, fourth, and fifth semiconductor layers;
an insulating layer located on a part of the first semiconductor layer between the second semiconductor layer and the third semiconductor layer; and
a third electrode located on the insulating layer, the third electrode being insulated from the second electrode.

7. The device according to claim 6, further comprising:
a sixth semiconductor layer contacting a fourth region of the first semiconductor layer, the sixth semiconductor layer being of the second conductivity type and including argon, an argon concentration of the sixth semiconductor layer being greater than the argon concentration of the second semiconductor layer and less than the argon concentration of the third semiconductor layer; and
a seventh semiconductor layer located on a portion of the sixth semiconductor layer, the seventh semiconductor layer being of the first conductivity type,
a distance between the fourth region and the third region being greater than the distance between the first region and the third region and less than the distance between the second region and the third region.

8. The device according to claim 6, wherein
the first region is located between the second region and the third region when viewed along a first direction, and
the first direction is from the first electrode toward the second electrode.

9. The device according to claim 6, wherein
the first region, the second region, and the third region extend in a second direction crossing a first direction, and
the first direction is from the first electrode toward the second electrode.

10. The device according to claim 6, wherein
the third region is arranged in a staggered configuration along a second direction and a third direction,
the second direction crosses a first direction,
the first direction is from the first electrode toward the second electrode,
the third direction crosses the first and second directions,
the first region is located in the second direction when viewed from the third region, and
the second region is located between two of the first regions in the third direction.

11. A semiconductor device, comprising:
a first electrode;
a first semiconductor layer connected to the first electrode, the first semiconductor layer being of a first conductivity type;
a second semiconductor layer contacting a first region of the first semiconductor layer, the second semiconductor layer being of a second conductivity type and including carbon;
a third semiconductor layer contacting a second region of the first semiconductor layer, the third semiconductor layer being of the second conductivity type, a carbon concentration of the third semiconductor layer being less than a carbon concentration of the second semiconductor layer;
a fourth semiconductor layer located on a portion of the second semiconductor layer, the fourth semiconductor layer being of the first conductivity type;
a fifth semiconductor layer located on a portion of the third semiconductor layer, the fifth semiconductor layer being of the first conductivity type;
a second electrode contacting a third region of the first semiconductor layer, a distance between the first region and the third region being less than a distance between the second region and the third region, the second electrode being connected to the second, third, fourth, and fifth semiconductor layers;
an insulating layer located on a part of the first semiconductor layer between the second semiconductor layer and the third semiconductor layer; and
a third electrode located on the insulating layer, the third electrode being insulated from the second electrode.

12. The device according to claim 11, further comprising:
a sixth semiconductor layer contacting a fourth region of the first semiconductor layer, the sixth semiconductor layer being of the second conductivity type and including carbon, a carbon concentration of the sixth semiconductor layer being less than the carbon concentration of the second semiconductor layer and greater than the carbon concentration of the third semiconductor layer; and
a seventh semiconductor layer located on a portion of the sixth semiconductor layer, the seventh semiconductor layer being of the first conductivity type,
a distance between the fourth region and the third region being greater than the distance between the first region and the third region and less than the distance between the second region and the third region.

13. The device according to claim 11, wherein
the first region is located between the second region and the third region when viewed along a first direction, and
the first direction is from the first electrode toward the second electrode.

14. The device according to claim 11, wherein
the first region, the second region, and the third region extend in a second direction crossing a first direction, and
the first direction is from the first electrode toward the second electrode.

15. The device according to claim 11, wherein
the third region is arranged in a staggered configuration along a second direction and a third direction,
the second direction crosses a first direction,
the first direction is from the first electrode toward the second electrode,
the third direction crosses the first and second directions,
the first region is located in the second direction when viewed from the third region, and
the second region is located between two of the first regions in the third direction.
